(19) United States
(12) Patent Application Publication
(10) Pub. No.: US 2024/0088034 A1
(43) Pub. Date: Mar. 14, 2024

(54) GAA DEVICE WITH THE SUBSTRATE INCLUDING EMBEDDED INSULATING STRUCTURE BETWEEN BSPDN AND CHANNELS

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Chih-Chao Yang, Glenmont, NY (US)

(21) Appl. No.: 17/930,739

(22) Filed: Sep. 9, 2022

(51) Int. Cl. H01L 23/528; H01L 21/762; H01L 27/12

(52) U.S. Cl. CPC H01L 23/5286; H01L 21/76283; H01L 27/12

(57) ABSTRACT

A microelectronic structure including a first nano device, where the first nano device includes a plurality of transistors. A bottom dielectric isolation located on the backside of each of the plurality of transistors of the first nano device. A separating dielectric layer located on the backside of the bottom dielectric isolation layer, where the separating dielectric layer is a continuous layer on the backside of each of the plurality of transistors of the first nano device.

### BACKGROUND

The present invention generally relates to the field of microelectronics, and more particularly to formation of dielectric layer that extends horizontal beneath the nano stack and the source/drain.

Nanosheet is the lead device architecture in continuing CMOS scaling. However, nanosheet technology has shown issues when scaling down such that as the devices become smaller and closer together, they are interfering with each other. When forming a via for connecting to the backside power rail the spacing of the via from the adjacent Si layers (i.e., the Si located beneath the source/drain or the nano stack) can lead to shorting. Furthermore, the distance between the Si layer and the backside power rail can lead to a short.

### BRIEF SUMMARY

Additional aspects and/or advantages will be set forth in part in the description which follows and, in part, will be apparent from the description, or may be learned by practice of the invention.

A microelectronic structure including a first nano device, where the first nano device includes a plurality of transistors. A bottom dielectric isolation located on the backside of each of the plurality of transistors of the first nano device. A separating dielectric layer located on the backside of the bottom dielectric isolation layer, where the separating dielectric layer is a continuous layer on the backside of each of the plurality of transistors of the first nano device.

A microelectronic structure including a nano device, where the nano device includes a plurality of transistors. A bottom dielectric isolation located on the backside of each of the plurality of transistors of the nano device. A separating dielectric layer located on the backside of the bottom dielectric isolation layer, where the separating dielectric layer is a continuous layer on the backside of each of the plurality of transistors of the nano device. A contact connected to a frontside surface of a source/drain of one of the transistors, where the contact includes a via that extends to the backside of the nano device. A shallow trench isolation layer located around a portion of the via of the contact.

The method including the steps of etching a plurality of alternating layers of sacrificial layers and channel layers located on top of a substrate to form a plurality of columns. Etching the substrate to form a plurality of initial trenches, where a trench is located between columns. Etching the substrate to laterally extend the initial trenches to form one continuous trench. Filling the continuous trench with a dielectric material to form the separating dielectric layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of multiple nano devices, in accordance with the embodiment of the present invention.

FIG. 2 illustrates a cross section X of the nano stack after the formation of the nano stack column, in accordance with the embodiment of the present invention.

FIG. 3 illustrates a cross section X of the nano stack after the formation of a temporary liner and after an initial trench is formed in the substrate, in accordance with the embodiment of the present invention.

FIG. 4 illustrates a cross section Y1 of the nano stack after the formation of a temporary liner and after an initial trench is formed in the substrate, in accordance with the embodiment of the present invention.

FIG. 5 illustrates a cross section X of the nano stack after the lateral etching of the substrate, in accordance with the embodiment of the present invention.

FIG. 6 illustrates a cross section Y1 of the nano stack after the lateral etching of the substrate, in accordance with the embodiment of the present invention.

FIG. 7 illustrates a cross section X of the nano stack after formation of the separating dielectric and the formation of the source/drain, in accordance with the embodiment of the present invention.

FIG. 8 illustrates a cross section Y1 of the nano stack after formation of the separating dielectric and the formation of the source/drain, in accordance with the embodiment of the present invention.

FIG. 9 illustrates a cross section X of the nano stack after formation of the gate, the frontside interlayer dielectric, and the contacts, in accordance with the embodiment of the present invention.

FIG. 10 illustrates a cross section Y1 of the nano stack after formation of the gate, the frontside interlayer dielectric, and the contacts, in accordance with the embodiment of the present invention.

FIG. 11 illustrates a cross section Y2 of the nano stack after formation of the gate, the frontside interlayer dielectric, and the contacts, in accordance with the embodiment of the present invention.

FIG. 12 illustrates a cross section X of the nano stack after formation of additional frontside interlayer dielectric, a connector, a back-end-of-the-line layer, and a carrier wafer, in accordance with the embodiment of the present invention.

FIG. 13 illustrates a cross section Y1 of the nano stack after formation of additional frontside interlayer dielectric, a connector, a back-end-of-the-line layer, and a carrier wafer, in accordance with the embodiment of the present invention.

FIG. 14 illustrates a cross section Y2 of the nano stack after formation of additional frontside interlayer dielectric, a connector, a back-end-of-the-line layer, and a carrier wafer, in accordance with the embodiment of the present invention.

FIG. 15 illustrates a cross section X of the nano stack after flipping the device over for backside processing and removal of most of the substrate, in accordance with the embodiment of the present invention.

FIG. 16 illustrates a cross section Y1 of the nano stack after flipping the device over for backside processing and removal of most of the substrate, in accordance with the embodiment of the present invention.

FIG. 17 illustrates a cross section Y2 of the nano stack after flipping the device over for backside processing and removal of most of the substrate, in accordance with the embodiment of the present invention.

FIG. 18 illustrates a cross section X of the nano stack after formation of a backside interlayer dielectric, a buried power rail, and a backside-power-distribution-network, in accordance with the embodiment of the present invention.

FIG. 19 illustrates a cross section Y1 of the nano stack after formation of a backside interlayer dielectric, a buried power rail, and a backside-power-distribution-network, in accordance with the embodiment of the present invention.

FIG. 20 illustrates a cross section Y2 of the nano stack after formation of a backside interlayer dielectric, a buried power rail, and a backside-power-distribution-network, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a dielectric layer beneath the source/drain and forming the dielectric layer beneath the nano stack. After the step where the nano stack columns are etched, then there is a step where the underlying substrate is etched to form trenches in the substrate. Then a lateral etching process is used to laterally etch the substrate at the trenches, causing the lateral/width dimensions of the trenches to increase. The lateral etching forms cavities beneath the nano stack and the source/drain region. The formation of the cavities leaves a small portion of the substrate in direct contact with the bottom dielectric isolation layer located beneath the nano stacks. The cavities beneath the nano stacks are connected to each other forming a continuous cavity. The cavities are filled with a dielectric material, such that the dielectric material is in direct contact with the backside of the bottom dielectric isolation layer.

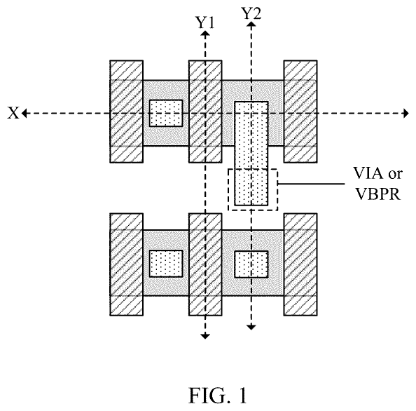

FIG. 1 illustrates a top-down view of multiple devices, in accordance with the embodiment of the present invention. The cross-section X extends horizontally through one of the nano stacks of one of the bottom devices. Cross section Y₁ is perpendicular to cross section X, where cross section Y₁ is through a gate region that spans across multiple nano stacks. Cross section Y₂ is perpendicular to cross section X, where cross section Y₂ is through the source/drain region of multiple nano stacks.

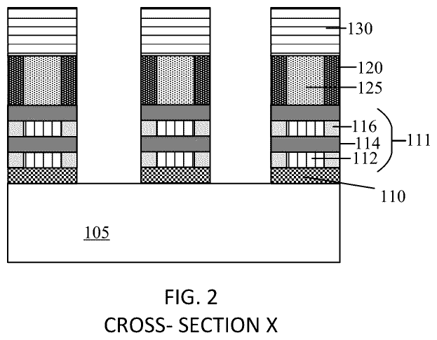

FIG. 2 illustrates the processing stage after fabrication of stacked layers to form the nano stacks. A bottom dielectric isolation layer 110 is located on top of a substrate 105. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

Alternating layers of channel layers 114 (nano sheets) and sacrificial layers 112 are etched to form a plurality of columns of nano stacks 111. Prior to the etching of the alternating layers, a first sacrificial layer (not shown), comprised of SiGe, where Ge is in the range of 40% to 70%, is selectively removed and replaced with a bottom dielectric isolation layer 110. The sacrificial layers 112 are recessed and an inner spacer 116 is formed in the space created by the recessing of the sacrificial layers 112. The plurality of sacrificial layers 112 can be comprised of SiGe, where Ge is in the range of about 15% to 35%. The inner spacer 116 is located adjacent to the sacrificial layers 112. One of the channel layers 114 is located above each of the sacrificial layers 112 and the inner spacer 116. The plurality of channel layers 114 can be comprised of, for example, Si. An upper spacer 120 is located on top of a channel layer 114 and the dummy gate 125 is located between sections of the upper spacer 120. The number of layers illustrated in each of the plurality of nano stacks 111 is for illustrative purposes only, each of the nano stacks 111 can be comprised fewer or more layers than what is illustrated by the Figures. Furthermore, the Figures illustrates that the upper spacer 120 is located on top of a channel layer 114, alternatively the upper spacer 120 can be located on top of the inner spacer 116 causing the dummy gate 125 to be located on top of a sacrificial layer 112. A hardmask 130 is located on top of the dummy gate 125 and on top of the upper spacer 120.

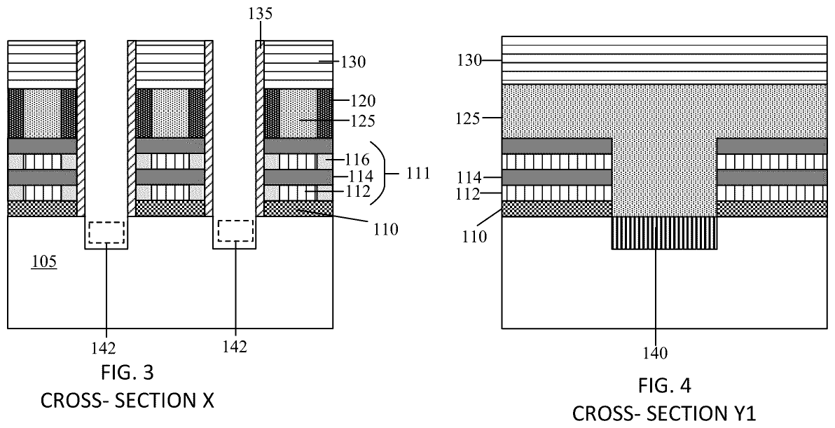

FIGS. 3 and 4 illustrate the processing stage after the formation of a temporary liner 135 and formation of the initial trench 142. A temporary liner 135 is formed on the exposed surfaces of the nano stack columns and on the exposed surfaces of the substrate 105. A portion of the temporary liner 135 is etched during the etching of the substrate 105. The substrate 105 is etched to form the initial trench 142, where the initial trench 142 is located between the nano stack columns, as illustrated by FIG. 3. FIG. 4 illustrates a cross section through the gate region. A trench was formed in the substrate 105 when the alternating channel layers 114 (nano sheets) and sacrificial layers 112 were etched to form the different nano devices. The trench is filled with a shallow trench isolation layer 140. As illustrated by FIGS. 3 and 4, the bottom dielectric layer 110 is located between the nano stack 111 and the substrate 105.

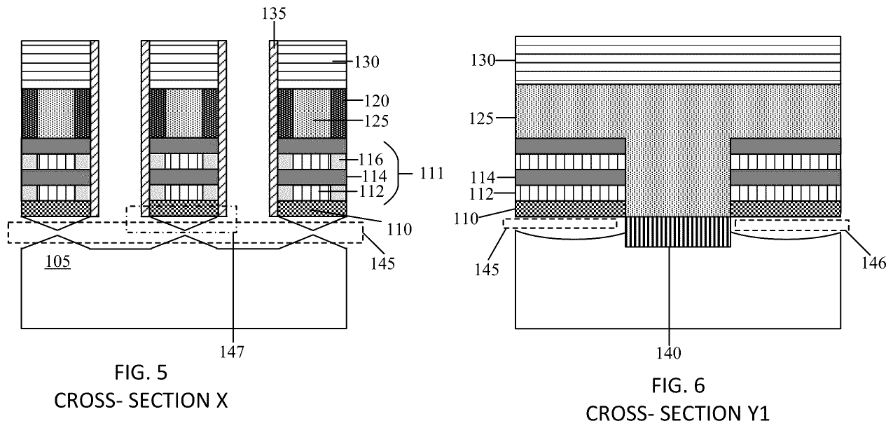

FIGS. 5 and 6 illustrate the processing stage after the lateral etching of the substrate 105. The initial trenches 142 are separate/independent trenches located in the substrate 105 prior to the lateral etching process. The substrate 105 is laterally etched, by, for example, a reactive ion etch with a low bias, where in this etching process laterally expands the initial trenches 142 to form cavity 145. The cavity 145 undercuts each of the nano columns, as illustrated by FIG. 5, and the lateral etching of the initial trenches 142 connects each of the trenches to each other to form the continuous cavity 145. A small portion of the substrate 105 remains beneath the nano columns, as emphasized by dashed box 147. The cavity 145 forms a continuous open space/void beneath the nano columns of cross-section X of the nano device. FIG. 6 illustrates a different perspective of the cavity 145 and a second cavity 146 (where the second cavity 146 is located beneath the adjacent/parallel nano device). The cavity 145 and the second cavity 146 extends underneath/under cuts the bottom dielectric layers 110. The cavity 145 and the second cavity 146 extend laterally to expose a sidewall of the shallow trench isolation layer 140.

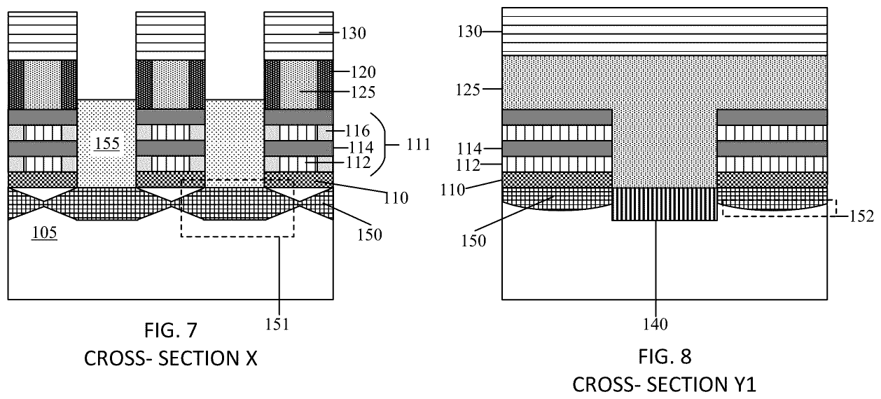

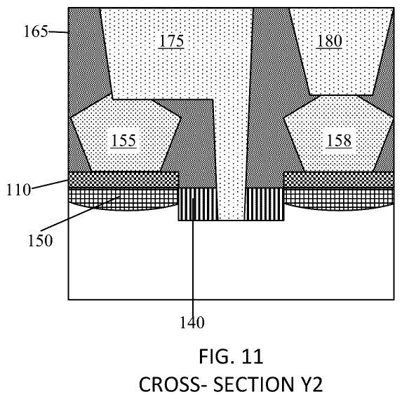

FIGS. 7 and 8 illustrate the processing stage after the formation of a separating dielectric layer 150 and the formation of the source/drain 155 and 158 (as shown in FIG. 11). The cavity 145 and the second cavity 146 are filled with a dielectric material to form the separating dielectric layer 150. The separating dielectric layer 150 has a top surface in contact with the remaining substrates 105 located beneath the nano columns, as illustrated by FIG. 7. The separating dielectric layer 150 has a bottom surface in contact with the substrate 105. As emphasized by dashed box 151, the separating dielectric layer 150 has a hexagonal shape cross-section. As illustrated by FIG. 8, the separating dielectric layer 150 has a top surface that is in contact with the bottom surface of the bottom dielectric isolation layer 110. A bottom surface of the separating dielectric layer 150 is in contact with the substrate 105. As dashed box 152 emphasizes, that the bottom surface/backside surface of the separating dielectric layer 150 is rounded when viewed in a cross section of the gate region and a cross section of the source/drain region. The separating dielectric layer 150 has a sidewall that is in contact with the shallow trench isolation layer 140. The temporary liner 135 is removed and a source/drain 155, 158 is formed between nano columns. The separating dielectric layer 150 is in contact with a bottom surface of the source/drain 155 as illustrated by FIG. 7.

The source/drain 155, 158 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

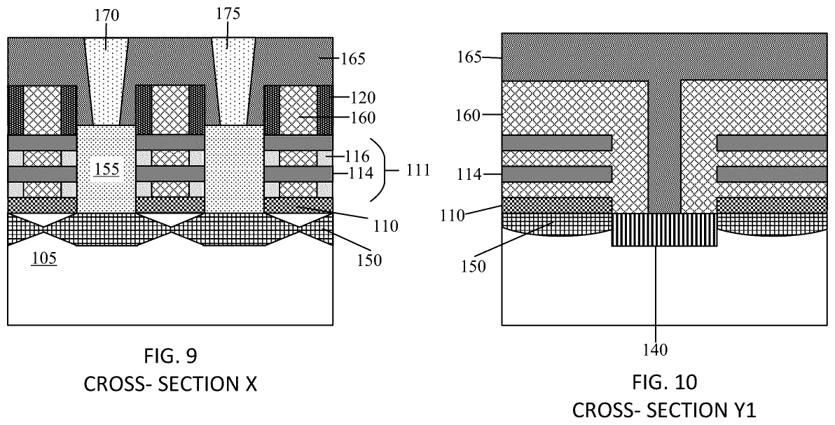

FIGS. 9, 10, and 11 illustrate the processing stage after formation of the gate 160, the frontside interlayer dielectric 165, and the contacts. The sacrificial layers 112 and the dummy gate 125 are selectively removed to form recesses (not shown). The recesses are filled with a gate material to form the gate 160. The gate 160 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. A frontside interlayer dielectric 165 is formed on top of the source/drain 155, 158, on top of the gate 160, and on top of the upper spacer 120. A trench (not shown) is formed in the gate 160 to expose a top surface of the shallow trench isolation layer 140. The trench is filled with the frontside interlayer dielectric 165 as illustrated by FIG. 10. Trenches (not shown) are formed in the frontside interlayer dielectric 165 to expose a top surface of the source/drains 155, 158. The trenches are filled with a conductive metal to form source drain contacts 170, 175, and 180. As illustrated by FIG. 11, prior to the metallization step to form the source/drain contacts, a via is formed in the frontside interlayer dielectric 165, and the shallow trench isolation layer 140. The via exposes a top surface of the substrate 105 and the shallow trench isolation layer 140 is located around a bottom section of the trench. The metallization step fills in the trench in the frontside interlayer dielectric 165 to form the source/drain contact 170, where the source/drain contact 170 includes a via (VBPR) that extends towards the backside of the device through the frontside interlayer dielectric 165, and the shallow trench isolation layer 150.

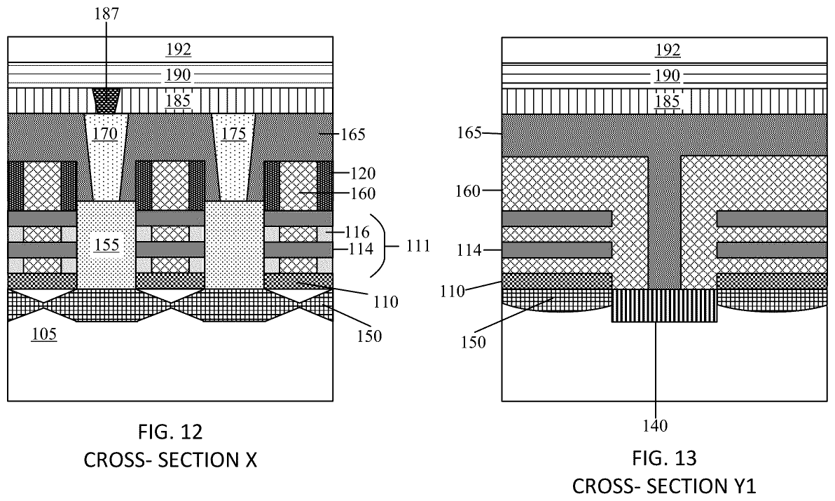

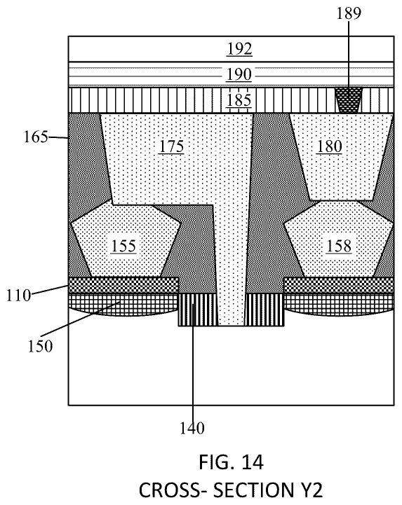

FIGS. 12, 13, and 14 illustrate the processing stage after formation of additional frontside interlayer dielectric 185, a connector 187, a back-end-of-the-line layer 190, and a carrier wafer 192. Additional frontside interlayer dielectric 185 is formed on top of the source/drain contacts 170, 175, 180, and the frontside interlayer dielectric 165. A connector 187, 189 is formed in the additional frontside interlayer dielectric 185. Connector 187 is in direct contact with the source/drain contact 170 and connector 189 is in direct contact with the source/drain contact 180. The back-end-of-the-line (BEOL) layers 190 are formed on top of the additional frontside interlayer dielectric 185 and the connector 187 and 189. A carrier wafer 192 is attached to a top surface of the BEOL layer 190.

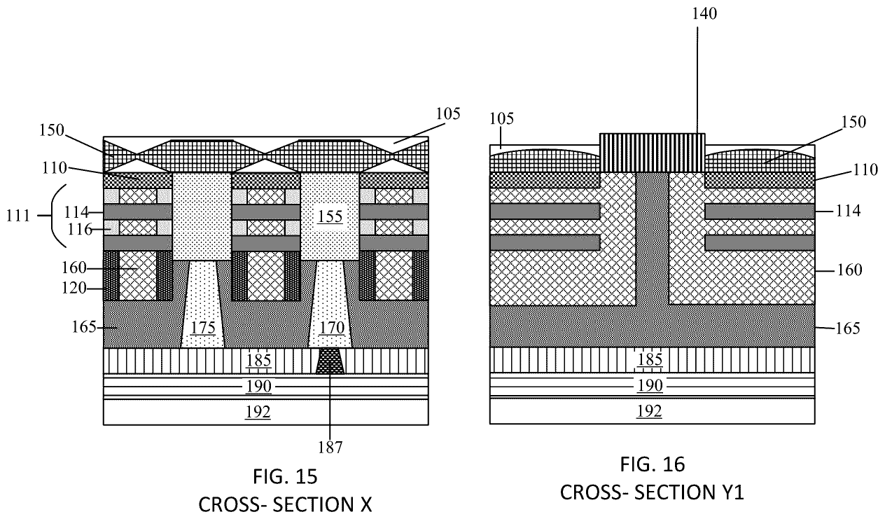

FIGS. 15, 16, and 17 illustrate the processing stage after flipping the device over for backside processing and removal of most of the substrate 105. The device/chip is flipped over to allow for the backside processing, such as the removal of the substrate 105. Most of the substrate 105 is removed but portions of the substrate around the separating dielectric layer 150 remain.

Typically, when removing the substrate from the backside of the device, the entirety of the substrate 105 is removed. This leads to the bottom dielectric layer, or another layer being exposed and could lead to errors or damages caused by the etching process. For example, the etching can expose gate material, or other conductive material by the accidental removal of dielectric material. Furthermore, if the substrate is not fully removed and the dielectric material is damage, then the substrate can act as a parasitic capacitor with a contact/gate/source/drain.

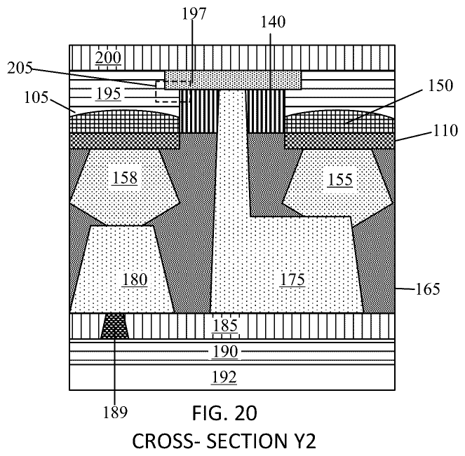

In contrast the present invention is able to prevent these types of errors/defects. The separating dielectric layer 150 located on the backside of the bottom dielectric isolation layer 110 acts as a buffer preventing the damage caused by the etching process and prevents the substrate from forming a parasitic capacitance. Also, the separating dielectric layer 150 increases the distance/space between the bottom dielectric isolation layer 110 and the remaining substrate 105 (as illustrate by FIGS. 16, 17, 19, and 20) that prevents the substrate 105 from forming a parasitic capacitance with the nano stack, gate 160, or other components.

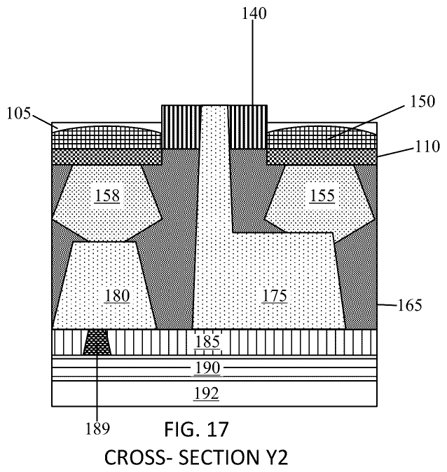

FIG. 15 illustrates portions of the substrate 105 remains after the etching process, but the separating dielectric layer 150 prevents the bottom dielectric isolation layer 110 from being damage from the etching process. FIG. 16 illustrates that the backside surface of the shallow trench isolation layer 140 is exposed by the removal of the substrate 105. A small portion of the substrate 105 (located on the backside of the separating dielectric layer 150) remains in contact with a portion of the sidewall of the shallow trench isolation layer 140. The separating dielectric layer 150 is in contact with the sidewall of the shallow trench isolation layer 140, such that the separating dielectric layer 150 is located between the bottom dielectric layer 110 and the remaining substrate 105. FIG. 17 illustrates that the etching process exposes a backside surface of the via of the source/drain contact 175. The shallow trench isolation layer 140 is located between the remaining substrate 105 and the via of the source/drain contact 175.

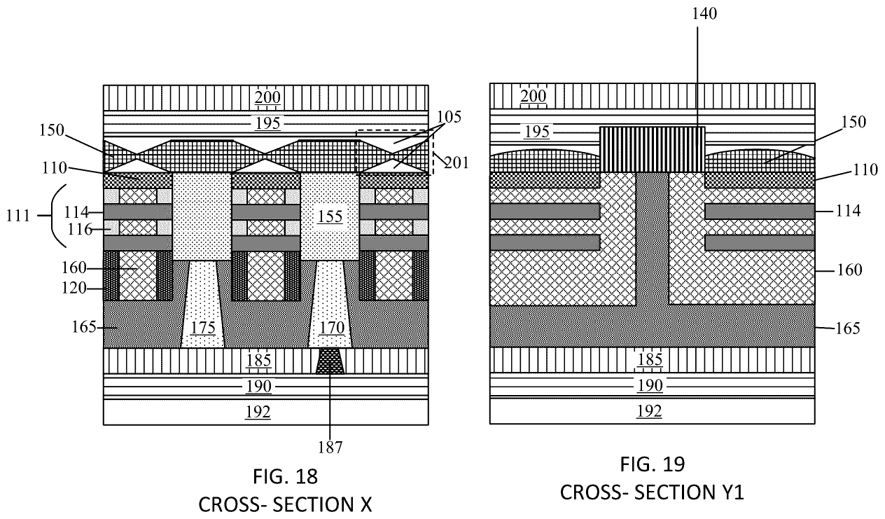

FIGS. 18, 19, and 20 illustrate the processing stage after formation of a backside interlayer dielectric 195, a buried power rail 197, and a backside-power-distribution-network 200. Dashed box 201 emphasizes that triangular shaped portions of the substrate 105 remain on the backside surface of the bottom dielectric isolation layer 110. The triangular shaped portion of the substrate 105 has one surface in contact with the bottom dielectric isolation layer 110 and two surfaces in contact with the separating dielectric layer 150. Furthermore, the separating dielectric isolation layer 150 is located between the peaks of two adjacent triangular shaped sections of the substrate 105. A backside interlayer dielectric 195 is formed on the remaining substrate 105, on the side and top of the shallow trench isolation layer 140, and on top of a backside surface of the via of the source/drain contact 175. A trench (not shown) is formed in the backside interlayer dielectric 195, where the trench exposes a backside surface of the shallow trench isolation layer 140 and the backside surface of the via of the source/drain contact 175. The buried power rail 197 is formed within the trench such that the buried power rail 197 is in direct contact with the backside surface of the shallow trench isolation layer 140 and in direct contact with the backside surface of the via of the source/drain contact 175. Dashed box 205 emphasizes that a portion of the backside interlayer dielectric 195 is located beneath a portion of the buried power rail 197. The backside power distribution network 200 is formed on top of the buried power rail 197 and on top of the backside interlayer dielectric 195.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nano device, wherein the first nano device includes a plurality of transistors;
a bottom dielectric isolation layer located on a backside of each of the plurality of transistors of the first nano device; and
a separating dielectric layer located on a backside of the bottom dielectric isolation layer, wherein the separating dielectric layer is a continuous layer on the backside of each of the plurality of transistors of the first nano device.

2. The microelectronic structure of claim 1, wherein the separating dielectric layer has a hexagonal cross-section across the first nano device.

3. The microelectronic structure of claim 2, further comprises:
a triangular shaped portion of a substrate is located on the backside of the bottom dielectric isolation layer.

4. The microelectronic structure of claim 3, wherein the triangular shaped portion of the substrate has one surface in direct contact with the backside surface of the bottom dielectric isolation layer, and the triangular shaped portion of the substrate has two surfaces in contact with the separating dielectric layer.

5. The microelectronic structure of claim 3, wherein the separating dielectric layer is located between a peak of the triangular shaped portion of the substrate and a second peak of a second triangular shaped portion of the substrate.

6. The microelectronic structure of claim 3, wherein the separating dielectric layer is in contact with a backside surface of a source/drain of each of the plurality of transistors of the first nano device.

7. The microelectronic structure of claim 1, further comprising:
a second nano device located adjacent and parallel to the first nano device, wherein the second nano device includes a plurality of second transistors;
a second bottom dielectric isolation layer located on the backside of each of the plurality of second transistors of the second nano device;
a second separating dielectric layer located on a backside of the second bottom dielectric isolation layer, wherein the second separating dielectric layer is a continuous layer on the backside of each of the plurality of second transistors of the second nano device.

8. The microelectronic structure of claim 7, further comprising:
a shallow trench isolation layer located between the separating dielectric layer located on backside of the first nano device and the second separating dielectric layer located on the backside of the second nano device.

9. The microelectronic structure of claim 8, wherein the separating dielectric layer and the second separating dielectric layer each have a rounded backside surface across a gate region of the first nano device and the second nano device, respectively.

10. The microelectronic structure of claim 9, further comprising:
a portion of the substrate remaining on the rounded backside surfaces of each of the separating dielectric layer and the second separating dielectric layer.

11. A microelectronic structure comprising:
a nano device comprising a plurality of transistors;
a bottom dielectric isolation located on a backside of each of the plurality of transistors of the nano device;
a separating dielectric layer located on a backside of the bottom dielectric isolation layer, wherein the separating dielectric layer is a continuous layer on the backside of each of the plurality of transistors of the nano device;
a contact connected to a frontside surface of a source/drain of one of the transistors, wherein the contact includes a via that extends to the backside of the nano device;
a shallow trench isolation layer located around a portion of the via of the contact.

12. The microelectronic structure of claim 11, wherein the separating dielectric layer is in contact with a first sidewall of the shallow trench isolation layer.

13. The microelectronic structure of claim 12, wherein the separating dielectric layer has a rounded backside surface across a source/drain region of the nano device.

14. The microelectronic structure of claim 13, further comprising:
a portion of a substrate remaining on the rounded backside surface of the separating dielectric layer.

15. The microelectronic structure of claim 14, wherein the portion of the substrate is in contact with the first sidewall of the shallow trench isolation layer.

16. The microelectronic structure of claim 15, wherein the shallow trench isolation layer is located between the via of the contact and the separating dielectric layer, and the shallow trench isolation layer is located between the via of the contact and the portion of the substrate.

17. The method comprising:
etching a plurality of alternating layers of sacrificial layers and channel layers located on top of a substrate to form a plurality of columns;
etching the substrate to form a plurality of initial trenches, wherein a trench is located between columns;
etching the substrate to laterally extend the initial trenches to form one continuous trench; and
filling the continuous trench with a dielectric material to form the separating dielectric layer.

18. The method of claim 17, further comprising:
forming a temporary liner on the exposed surfaces of the columns prior to forming the initial trenches;
removing the temporary liner after the formation of the separating dielectric layer.

19. The method of claim 17, wherein a triangular shaped portion of the substrate is located on the backsides of each of the columns after the etching process to laterally extend the initial trenches.

20. The method of claim 19, wherein the separating dielectric layer is located between a peak of the triangular shaped portion of the substrate and a second peak of a second triangular shaped portion of substrate.
